(19) United States
(12) Patent Application Publication
(10) Pub. No.: US 2022/0221353 A1
(43) Pub. Date: Jul. 14, 2022

(54) SEMICONDUCTOR FORCE SENSORS

(71) Applicant: TEXAS INSTRUMENTS INCORPORATED, Dallas, TX (US)

(72) Inventors: Tobias Bernhard FRITZ, Mainburg (DE); Baher S. HAROUN, Allen, TX (US); Benjamin Stassen COOK, Los Gatos, CA (US); Sreenivasan Kalyani KODURI, Dallas, TX (US); Michael SZELONG, Freising (DE); Ernst MUELLNER, Muenchen (DE)

(21) Appl. No.: 17/538,782

(22) Filed: Nov. 30, 2021

Related U.S. Application Data
(60) Provisional application No. 63/136,239, filed on Jan. 12, 2021.
(60) Provisional application No. 63/244,064, filed on Sep. 14, 2021.

(51) Int. Cl. G01L 1/18; H01L 23/31; H01L 23/495

(52) U.S. Cl. CPC G01L 1/18; H01L 23/3107; H01L 23/49555; H01L 23/4952; H01L 23/49503

(57) ABSTRACT

A force sensor including a semiconductor die, and a die pad coupled to the semiconductor die, the semiconductor die configured to detect a force in the die pad. In addition, the force sensor includes a mold compound covering the semiconductor die and having an outer perimeter, a first side, and a second side opposite the first side, the outer perimeter extending between the first side and the second side, the die pad exposed out of the mold compound along the first side. Further, the force sensor includes a mounting frame engaged with the die pad along the second side of the mold compound, the mounting frame including multiple mounting pads extended outward in multiple directions from the outer perimeter.

### CROSS-REFERENCE TO RELATED APPLICATIONS

The present application claims priority to U.S. Provisional Patent Application No. 63/136,239, filed Jan. 12, 2021, and entitled titled “Semiconductor Package Configurations For Mechanical Force Sensors,” and U.S. Provisional Patent Application No. 63/244,064, which was filed Sep. 14, 2021, and entitled “Semiconductor Package Configurations For Mechanical Force Sensors,” the contents of each being incorporated herein by reference in their entirety.

### BACKGROUND

Force sensors are useful to detect one or more forces experienced by a member of interest. In some instances, a force sensor may be useful to detect stress, torque, compression, strain, tension, etc. experienced by the member of interest (e.g., a shaft, strut, beam). To facilitate the detection of these forces, the force sensor (or some component thereof) is mounted to the member so forces experienced by the member may be transferred to the force sensor during operations.

### SUMMARY

Some examples described herein include a force sensor. In some examples, the force sensor includes a semiconductor die, and a die pad coupled to the semiconductor die, the semiconductor die configured to detect a force in the die pad. In addition, the force sensor includes a mold compound covering the semiconductor die and having an outer perimeter, a first side, and a second side opposite the first side, the outer perimeter extending between the first side and the second side, the die pad exposed out of the mold compound along the first side. Further, the force sensor includes a mounting frame engaged with the die pad along the second side of the mold compound, the mounting frame including multiple mounting pads extended outward in multiple directions from the outer perimeter.

In some examples, the force sensor includes a semiconductor die configured to detect a force and a mold compound covering the semiconductor die, the mold compound including an outer perimeter. In addition, the force sensor includes a die pad including a portion engaged with the semiconductor die and multiple mounting pads extended beyond the outer perimeter of the mold compound on opposite sides of the mold compound.

In some examples, the force sensor includes a semiconductor die configured to detect a force and a die pad coupled to the semiconductor die. In addition, the force sensor includes a mold compound covering the semiconductor die and having an outer perimeter, a first side, and a second side opposite the first side, the outer perimeter extending between the first side and the second side, the die pad exposed out of the mold compound along the first side. Further, the force sensor includes a mounting frame engaged with the die pad along the first side of the mold compound, the mounting frame having multiple mounting pads positioned outside of the outer perimeter on opposing sides of the mold compound.

### BRIEF DESCRIPTION OF THE DRAWINGS

FIG. 1 is a perspective view of a force sensor coupled to a shaft according to some examples.

FIG. 2A is a perspective view of a force sensor for mounting to a member of interest according to some examples.

FIG. 2B is a bottom view of a force sensor for mounting to a member of interest according to some examples.

FIG. 2C is a cross-sectional view of a force sensor for mounting to a member of interest according to some examples.

FIG. 2D is a cross-sectional view of a force sensor for mounting to a member of interest according to some examples.

FIG. 3A is a cross-sectional view of a force sensor for mounting to a member of interest according to some examples.

FIG. 3B is a cross-sectional view of a force sensor for mounting to a member of interest according to some examples.

FIG. 3C is a cross-sectional view of a force sensor for mounting to a member of interest according to some examples.

FIG. 3D is a cross-sectional view of a force sensor for mounting to a member of interest according to some examples.

FIG. 4A is a bottom view a force sensor for mounting to a member of interest according to some examples.

FIG. 4B is a bottom view a force sensor for mounting to a member of interest according to some examples.

FIG. 4C is a bottom view of a force sensor for mounting to a member of interest according to some examples.

FIG. 5 is a cross-sectional view of a force sensor for mounting to a member of interest according to some examples.

FIG. 6A is a top view of a force sensor for mounting to a member of interest according to some examples.

FIG. 6B is a cross-sectional view of a force sensor for mounting to a member of interest according to some examples.

FIG. 6C is a top view of a force sensor for mounting to a member of interest according to some examples.

FIG. 7 is a perspective view of a force sensor for mounting to a member of interest according to some examples.

FIG. 8 is a perspective view of a force sensor for mounted to a member of interest according to some examples

FIG. 9A is a cross-sectional view of a force sensor mounted to a member of interest according to some examples.

FIG. 9B is a cross-sectional view of a force sensor mounted to a member of interest according to some examples.

FIG. 10A is a cross-sectional view of a force sensor for mounting to a member of interest according to some examples.

FIG. 10B is a bottom view of a force sensor for mounting to a member of interest according to some examples.

### DETAILED DESCRIPTION

A force sensor may be mounted to a member of interest for detecting (e.g., directly, indirectly) forces within the member. The force sensor is mounted to the member of interest, and forces experienced by the member may then be transferred to the force sensor via the mounting. Some mounting devices or techniques may dampen or absorb forces that are transferred from the member of interest thereby causing the force sensor to be less effective at detecting these forces during operations. Thus, mounting the force sensor to the member of interest may have a meaningful effect on the quality of data that may be obtained by the force sensor during operations.

Accordingly, examples described herein include force sensors including mounting frames and/or components for mounting the force sensor to a member of interest (e.g., a rotating shaft, structural beam). In some examples, the force sensors may include a semiconductor die that is secured to the member of interest via a mounting frame that is coupled to or integrated with a die pad for the semiconductor die. As is described in more detail herein, the mounting frame is configured to transfer forces from the member of interest to the semiconductor die of the semiconductor package. Thus, forces experienced by the member may be accurately and reliably detected.

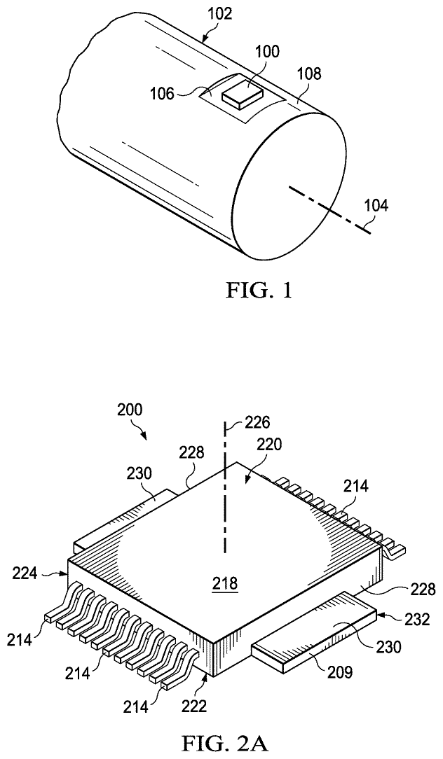

Referring now to FIG. 1, a force sensor 100 according to some examples is shown mounted to a shaft 102 that is rotatable about a central or longitudinal axis 104. The shaft 102 may be a rotating shaft of a pump, compressor, drivetrain or other mechanical system. The force sensor 100 is mounted to a mounting surface 106 which may include a planar or facetted surface that is defined on the otherwise curved outer surface 108 of shaft 102.

During operations, the force sensor 100 may detect, via the engagement with mounting surface 106, the forces experienced by the shaft 102. For instance, the shaft 102 may experience a torque about longitudinal axis 104, axial stress (e.g., from tension or compression along longitudinal axis 104), bending stress, strain, etc. These various forces and stresses that may be experienced by the shaft 102 may be collectively and generally referred to herein as “forces.” The force sensor 100 may detect (e.g., directly or indirectly) any one or more of these forces during operations thereby allowing personnel to monitor the operating conditions of the shaft 102.

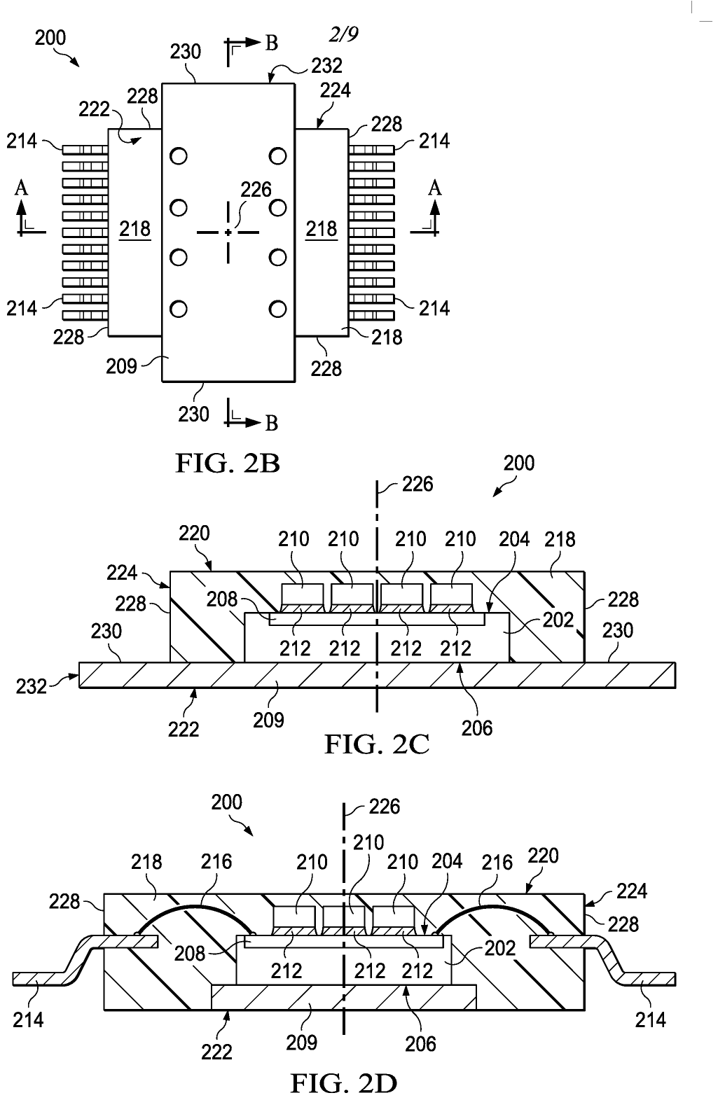

Referring now to FIGS. 2A-2D, a force sensor 200 that may be the force sensor 100 of FIG. 1 is shown according to some examples. FIGS. 2A and 2B show perspective and bottom views, respectively, of the force sensor 200, and FIGS. 2C and 2D show cross-sectional views of force sensor 200 along sections B-B and A-A, respectively, in FIG. 2B. FIGS. 2A-2D may be collectively referred to herein as “FIG. 2.”

As best shown in FIGS. 2C and 2D, the force sensor 200 is a semiconductor package that includes a semiconductor die 202 having a device side 204 and non-device side 206 opposite the device side 204. An active circuit 208 (or more simply “circuit 208”) is formed on the device side 204. The non-device side 206 of semiconductor die 202 is secured to a die pad 209 via a die attach layer (not shown).

A number of passive devices 210 are coupled to the circuit 208 along device side 204. The passive devices 210 may be coupled to circuit 208 via solder members 212 (which may be referred to as “solder bumps”). In some examples, the passive devices 210 may include capacitors, inductors, antennas, coils and/or other components that may perform a function (or functions) either independently of or along with circuit 208. In some examples, the passive devices 210 may include an antenna and a filter that are coupled to circuit 208 and that are configured to receive and/or send wireless electronic signals to other devices (e.g., computers, semiconductor chip packages) either directly or via a network. Specifically, during operations, the antenna, formed or defined by the passive devices 210, may transmit output signals of the force sensor 200 that may include, or be indicative of, forces detected by the force sensor 200.

The circuit 208 may be coupled to conductive terminals 214 via bond wires 216. In some examples, the conductive terminals 214 may be so-called gull-wing leads. However, the force sensor 200 may include a quad flat no-lead (QFN) package and the conductive terminals 214 may be arranged and designed for inclusion therein.

A mold compound 218 (e.g., a polymer or resin material) may cover the semiconductor die 202, bond wires 216, passive devices 210, and a portion of the conductive terminals 214. The mold compound 218 may protect the components of semiconductor die 202 bond wires 216, passive components 210, and conductive terminals 214 from the outside environment (e.g., specifically from dust, liquid, light, contaminants in the outside environment), and may prevent contact with conductive surfaces or members during operations. As used herein, the term “mold compound” includes a covering for a semiconductor die that is formed through any suitable process, such as a cavity molding operation, glob encapsulation, dam-and-fill type encapsulation, etc.

The mold compound 218 may include a first side 220, a second side 222 opposite first side 220, and an outer perimeter 224 extending between the first side 220 and the second side 222 along an axis 226 that extends through (e.g., perpendicularly through) the sides 220, 222. As best shown in FIGS. 2A and 2B, the mold compound 218 may be shaped as a rectangular parallelepiped in some examples. Accordingly, the first side 220 and second side 222 may be parallel planar surfaces that are spaced from one another along axis 226, and the outer perimeter 224 may include four planar sides surfaces 228 that extend axially (with respect to axis 226) between sides 220, 222. However, mold compound 218 may be formed in a variety of other three-dimensional shapes in other examples.

As shown in FIG. 2D, the conductive terminals 214 may be curved or bent toward the second side 222. In some examples, the conductive terminals 214 may be curved or bent toward the first side 220. In some examples, the conductive terminals 214 may extend out of the mold compound along other surfaces (other than the side surfaces 228 forming the outer perimeter 224). For instance, the conductive terminals 214 may extend out of the mold compound 218 along the first side 220 in some examples.

The die pad 209 may be exposed out of the mold compound 218 along second side 222. In particular, die pad 209 (or a face or surface thereof) may be flush or co-planar with second side 222 of mold compound 218. Also, the die pad 209 may extend beyond the outer perimeter 224 of mold compound 218 on opposing side surfaces 228 that are opposite (e.g., radially opposite) one another about axis 226. In particular, as best shown in FIGS. 2A and 2B, the die pad 209 may include a pair of mounting pads 230 that are extending outward in multiple directions from the outer perimeter 224 (e.g., in radially opposite directions about axis 226). Thus, the die pad 209 may form a mounting frame 232 having the mounting pads 230 for securing force sensor 200 to a member of interest (e.g., mounting surface 106 on shaft 102 shown in FIG. 1). The mounting pads 230 are in a common plane with the die pad 209.

During operations, the mounting pads 230 may be secured to a surface of a member of interest via an adhesive, welding (e.g., ultrasonic welding), a mounting device (e.g., screw, nail, rivet, bolt, pin). Thereafter, forces experienced by the member of interest may be transferred to the circuit 208 via the mounting pads 230 of die pad 209, and the transferred forces may then be detected by circuit 208. In some examples, the circuit 208 may detect the transferred forces via piezoresistive changes caused in the circuit 208 by the transferred forces. The circuit 208 may then provide an output signal (which may include the detected force(s) and/or a value indicative thereof) to another electronic device via the passive devices 210 (e.g., which may include antenna(s), coil(s), capacitor(s), inductor(s) as described above). In some examples, the circuit 208 may provide an output signal to another electronic device via the conductive terminals 214 which may further be coupled to suitable conductive connectors, terminals, pads, etc. on another device, a printed circuit board, or other suitable device.

Without being limited to this or any other theory, by positioning mounting pads 230 outside of the outer perimeter 224 of mold compound 218, they may be more easily accessed for securely mounting force sensor 200 to a member of interest (e.g., shaft 102 in FIG. 1). Also, by extending mounting pads 230 outward from outer perimeter 224 on opposite sides (and in opposite directions) of mold compound 218, the connection or mounting points of the force sensor 200 may be spaced (e.g., in a radial direction with respect to axis 226) to allow differential force measurements (e.g., for shear, strain, bending) to be more accurately transferred thereto.

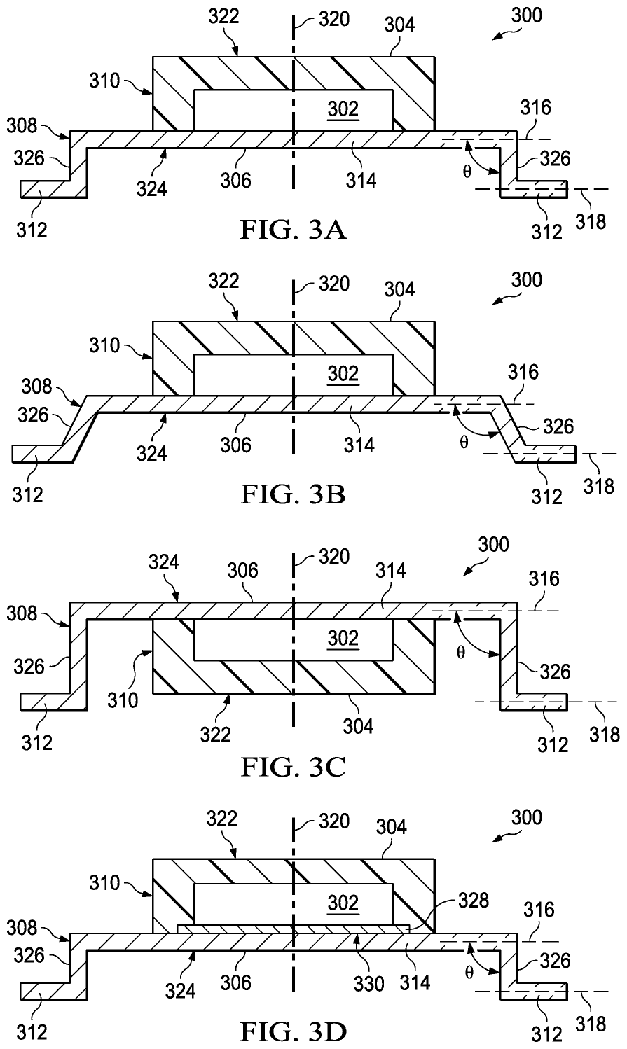

Referring now to FIGS. 3A-3D, examples of force sensors 300 that may be the force sensor 100 in FIG. 1 are shown. FIGS. 3A-3D may be collectively referred to herein as “FIG. 3.” The force sensors 300 shown in FIGS. 3A-3D may be similar to the force sensor 200 shown in FIGS. 2A-2D and may include a number of the same components described above (however, some of these shared components may not be shown in FIGS. 3A-3D so as to simplify the drawings and the description below).

Referring specifically to FIG. 3A, in some examples force sensor 300 may include semiconductor die 302 that is similar to the semiconductor die 202 described above (FIGS. 2C and 2D). The semiconductor die 302 is covered by a mold compound 304 that may be similar to the mold compound 218 described above (FIGS. 2A-2D). Also, the semiconductor die 302 may be mounted to a die pad 306 that is integrated within a mounting frame 308 that extends beyond the outer perimeter 310 of mold compound 304. Thus, the die pad 306 and mounting frame 308 form a monolithic body that is made up of one continuous piece of material (e.g., a metallic material).

The mounting frame 308 includes mounting pads 312 that may function in the manner described above for mounting pads 230 (FIGS. 2A-2D); however, the mounting pads 312 are positioned in a different plane than other portions of the die pad 306. In particular, the mounting frame 308 may include a portion 314 that is engaged with the semiconductor die 302 and is in a first plane 316. The portion 314 may form the die pad 306. Also, the mounting pads 312 of the mounting frame 308 are in a second plane 318 that is spaced from the first plane 316 along an axis 320 extending between (e.g., perpendicularly between) first and second sides 322 and 324, respectively, of mold compound 304 (e.g., similar to axis 226 in FIGS. 2A-2D). The mounting frame 308 may also include connection portions 326 extending between the portion 314 and the mounting pads 312. The portion 314 is positioned between the mounting pads 312 and the first side 322 along the axis 320. The connections portions 326 may extend at a non-zero angle θ to the first plane 316 (and thus also the second plane 318). In some examples the angle θ may be about 90°.

During operations, the mounting pads 312 may be secured to a surface of a member of interest via an adhesive, welding (e.g., ultrasonic welding), a mounting device (e.g., screw, nail, rivet, bolt, pin), etc. Thereafter, forces experienced by the member of interest may be transferred to a circuit on the semiconductor die (e.g., circuit 208 in FIGS. 2C and 2D) via the mounting pads 312 of die pad 306, and the transferred forces may then be detected as described above. Without being limited to this or any other theory, by spacing the mounting pads 312 from the portion 314 via connection portions 326, semiconductor die 302 and mold compound 304 along axis 320, the semiconductor die 302 may be suspended from the member of interest via the mounting frame 308. Thus, during operations forces experienced by the member of interest (e.g., shaft 102 in FIG. 1) may cause deformation of mounting frame 308 thereby magnifies forces transferred to semiconductor die 302. Accordingly, mounting frame 308 may allow the sensitivity of force sensor 300 to be enhanced.

Referring specifically now to FIG. 3B, in some examples the angle θ of the connection portions 326 is greater than or equal to 90° and less than or equal to 180°. In some example, the angle θ may be an obtuse angle that is greater than 90° and less than 180°. In some examples, the angle θ may be approximately 45°. Without being limited to this or any other theory, an acute angle θ may allow components of forces that are aligned (or parallel) with the planes 316 or 318 to be more effectively transferred to semiconductor die 302 via the mounting frame 308.

Referring specifically now to FIG. 3C, in some examples the semiconductor die 302 and the mold compound 304 may be coupled to the portion 314 to thereby place the first side 322 and the second side 324 between the mounting pads 312 and the portion 314 along axis 320. Without being limited to this or any other theory, arrangement of the mounting frame 308, semiconductor die 302 and mold compound 304 in the manner shown in FIG. 3C may allow the mounting frame to cover (at least partially) the semiconductor die 302 and mold compound 304 and therefore provide some protection to these components from impact during operations. However, the mounting frame 308 of force sensor 300 in FIG. 3C may continue to function as a force magnifier for the same reasons provided above.

Referring specifically now to FIG. 3D, in some examples the mounting frame 308 may be separately engaged with a die pad 328 that is engaged with a device side 330 of the semiconductor die 302. The die pad 328 may be exposed out of the mold compound 304 along second side 324 and may be engaged (e.g., welded, adhered, bolted, pinned) to the portion 314 of mounting frame 308. Without being limited to this or any other theory, by including a separate mounting frame 308 (e.g., separate from the die pad 328), the manufacturing process for semiconductor die 302, die pad 328, and mold compound 304 may be simplified and separate from the manufacturing of mounting frame 308, which may involve different tooling, materials, etc. Thus, an overall manufacturing process for force sensor 300 may be simplified.

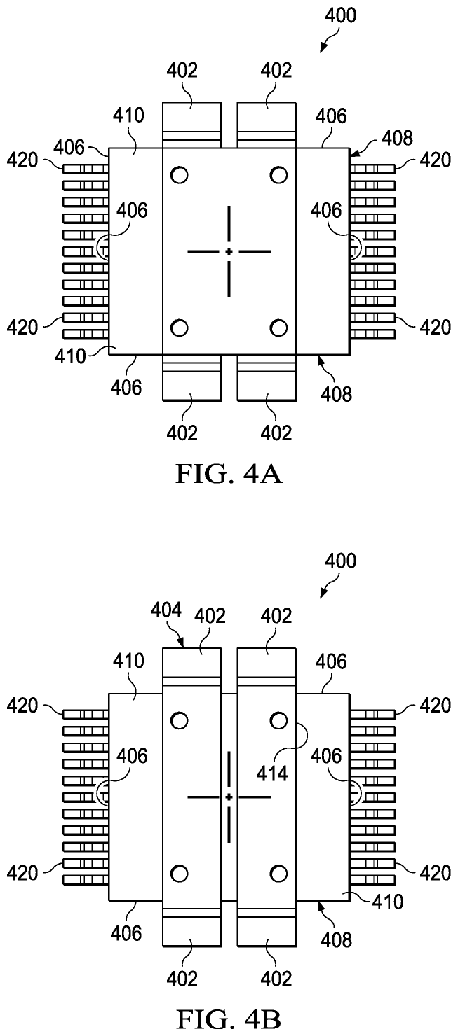

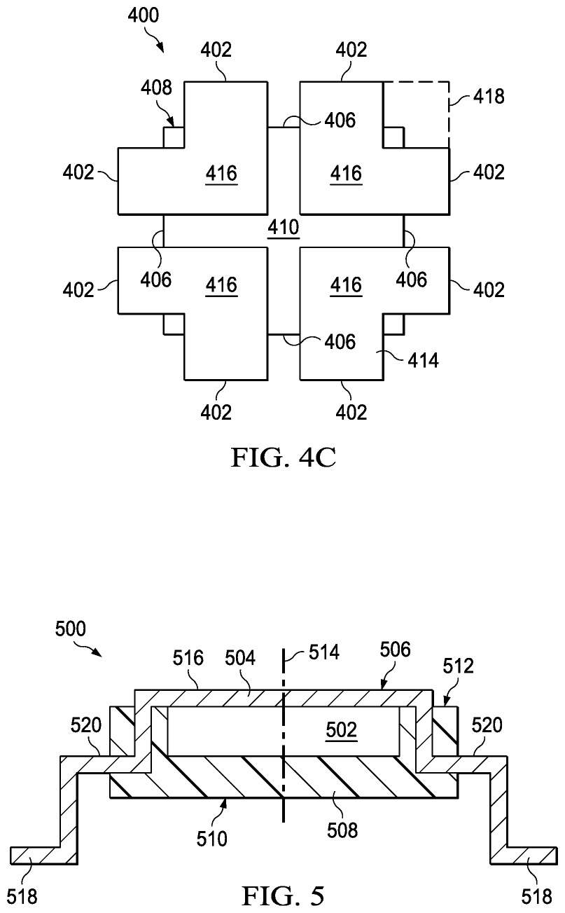

Referring now to FIGS. 4A-4C, examples of force sensors 400 that may be the force sensor 100 in FIG. 1 are shown. FIGS. 4A-4C may be collectively referred to herein as “FIG. 4.” The force sensors 400 shown in FIGS. 4A-4C may be similar to the force sensor 200 shown in FIGS. 2A-2D and may include a number of the same components described above (however, some of these shared components may not be shown in FIGS. 4A-4C so as to simplify the drawings and the description below).

FIGS. 4A-4C show examples in which the mounting pads 402 of a mounting frame 404 for attaching the force sensor 400 to a member of interest (e.g., shaft 102 in FIG. 1) may be split into multiple mounting pads 402 on a side 406 (or sides 406) of an outer perimeter 408 of a mold compound 410 of the force sensor 400. Referring specifically to FIG. 4A, in some examples a portion 414 of the mounting frame 404 (which may be engaged with or integrated with a die pad of the force sensor as described above) may be a singular piece, and the mounting pads 402 outside of the outer perimeter 408 of mold compound 410 are split into multiple mounting pads 402 on the opposite sides 406. Referring specifically to FIG. 4B, in some examples both the mounting pads 402 and the portion 414 are split into two portions. Without being limited to this or any other theory, by splitting the mounting pads 402 and/or the portion 414, differences in forces (e.g., shear) may transferred to the split mounting pads 402 on a given side 406 of outer perimeter 408 may be more effectively transferred through mounting frame 404 and detected by the force sensors 400. Referring specifically to FIG. 4C, in some examples the portion 414 may be split into more than two (e.g., four) separate pieces 416 that are each connected to a mounting pad 402 or multiple mounting pads 402 that are extended from the sides 406 of outer perimeter 408. In some examples, each piece 416 of the portion 414 may be engaged with multiple mounting pads 402 extended from different sides 406, or may be engaged with a single mounting pad 402 that may extend from outer perimeter 408 along multiple sides 406 such as is shown via the dotted line 418 in FIG. 4C.

Referring again to FIGS. 4A and 4C, force sensors may include conductive terminals 420 that extend out of the mold compound 410. The conductive terminals 420 may be similar to the conductive terminals 214 shown in FIGS. 2A-2D and described above.

Referring now to FIG. 5, examples of a force sensor 500 that may be the force sensor 100 in FIG. 1 is shown. The force sensor shown in FIG. 5 may be similar to the force sensor shown in FIGS. 2A-2D and may include a number of the same components described above (however, some of these shared components may not be shown in FIG. 5 so as to simplify the drawings and the description below).

As shown in FIG. 5, force sensor 500 includes a semiconductor die 502 mounted to a die pad 504 that is integrally formed within a mounting frame 506 as described above. A mold compound 508 covers the semiconductor die 502. The mold compound 508 includes a first side 510 and a second side 512 spaced from and opposite first side 510 along an axis 514. A portion 516 of the mounting frame 506 (and which forms the die pad 504) is exposed along the second side 512. The mounting frame 506 also includes multiple mounting pads 518 that are coupled to portion 516 via connection portions 520. As described above for the force sensor 300 shown in FIG. 3C, the semiconductor die 502 and mold compound 508 are coupled to portion 516 to thereby place the first and second sides 510, 512 between the portion 516 and mounting pads 518 along the axis 514. The connection portions 520 extend through the mold compound 508 between the portion 516 and mounting pads 518. Accordingly, forces may be transferred from the mounting frame 506 to the semiconductor die 502 both at the engagement with semiconductor die 502 and the portion 516 and between the connection portions 520 and semiconductor die 502 via the mold compound 508.

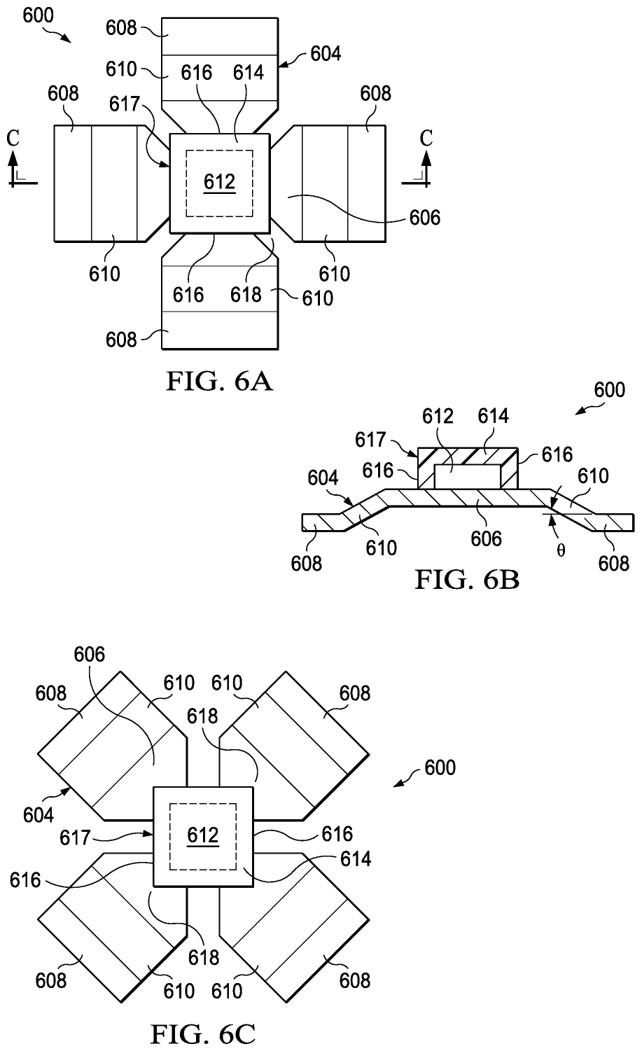

Referring now to FIGS. 6A-6C, examples of force sensors 600 that may be the force sensor 100 in FIG. 1 are shown. The force sensors 600 shown in FIGS. 6A-6C may be similar to the force sensors 200 shown in FIGS. 2A-2D and may include a number of the same components described above (however, some of these shared components may not be shown in FIGS. 6A-6C so as to simplify the drawings and the description below.

Force sensors 600 may include a mounting frame 604 having a portion 606 and multiple mounting pads 608 connected to the portion 606 via multiple connection portions 610. As best shown in FIG. 6B, the force sensor 600 also includes a semiconductor die 612 mounted to the portion 606 of mounting frame 604. Accordingly, the portion 606 forms a die pad for the semiconductor die 612 of the force sensor 600. Force sensor 600 also includes a mold compound 614 that covers the semiconductor die 612. As shown in FIG. 6A, each mounting pad 608 may be arranged or aligned along a side 616 of the outer perimeter 617 of mold compound 614 and is positioned outside of outer perimeter 617. Accordingly, each connection portion 610 of the force sensor 600 in FIG. 6A extends outward from portion 606 along each side 616 of outer perimeter 617. As shown in FIG. 6B, in some examples each mounting pad 608 may be arranged or aligned with a corner or junction 618 of two sides 616 of the outer perimeter 617. Accordingly, each connection portion 610 of the force sensor in FIG. 6C extends outward from portion 606 at a corner 618 of outer perimeter 617. For the force sensors 600 of both FIGS. 6A and 6C, there are a total of four mounting pads 608 that are uniformly spaced about the outer perimeter 617 (e.g., each mounting pad 608 is spaced approximately 90° from each adjacent mounting pad 608 about outer perimeter).

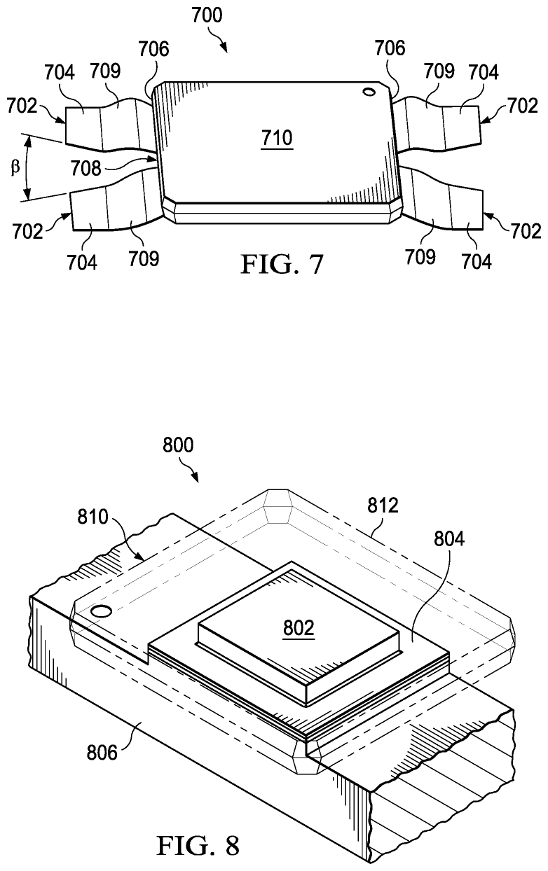

Referring now to FIG. 7, a force sensor 700 that may be the force sensor 100 in FIG. 1 is shown. The force sensor 700 shown in FIG. 7 may be similar to the force sensor 200 shown in FIGS. 2A-2D and may include a number of the same components described above (however, some of these shared components may not be shown in FIG. 7 so as to simplify the drawings and the description below).

The force sensor 700 includes a mounting frame 702 including multiple mounting pads 704 that are extended outward from opposing sides 706 of an outer perimeter 708 of a mold compound 710. The mounting pads 704 are coupled to a portion (not shown) via connection portions 709, wherein the portion (not shown) may be engaged or integrated with a die pad coupled to a semiconductor die (not shown) as described above. The connection portions 709 on each of the opposing sides 706 flare or diverge away from one another moving outward from the opposing sides 706. Accordingly, mounting frame 702 may transfer (and potentially amplify) forces transferred to mounting pads 704 in multiple directions along a plane including or parallel to the mounting pads 704 during operations. In some examples, the connection portions 709 on a given side 706 of outer perimeter 708 may diverge away from one another at an angle β that may range from 0° to 90°, such as from 20° to 45°. In some examples, the angle β is chosen to provide suitable flexibility to the mounting pads 704 and to facilitate sufficient conformance of the mounting pads 704 for engagement with the member of interest (e.g., shaft 102 in FIG. 1). In some examples, the angle β may be chosen based on the geometrical constraints of the member of interest, and/or to magnify the force transferred through the mounting frame 702. For instance, in some examples the angle β may be greater than 0° and less than or equal to 90°, such as greater than or equal to 20° and less than or equal to 45°. The independent legs allow for more independent movement and placement of the mounting pads for more efficient mounting to the member of interest. Flaring out may allow differential forces to transfer through the mounting frame in multiple directions.

Referring now to FIG. 8, a force sensor 800 that may be the force sensor 100 in FIG. 1 is shown. The force sensor 800 shown in FIG. 8 may be similar to force sensor 200 shown in FIGS. 2A-2D and may include a number of the same components described above (however, some of these shared components may not be shown in FIG. 8 so as to simplify the drawings and the description below).

Force sensor 800 includes a semiconductor die 802 that is mounted to a die pad 804. The die pad 804 may be directly engaged with a member 806 that may include a structural component of a mechanical system (e.g., a beam, strut, column). The die pad 804 may be secured to the member 806 with an adhesive. During operations forces transferred from the member 806 to the die pad 804 are also transferred to the semiconductor die 802. The semiconductor die 802 may include a circuit (not shown) that is configured to detect the forces transferred from die pad 804 (e.g., via piezoresistive changes as described above). For the force sensor 800, the die pad 804 therefore forms a mounting frame that engages with the member 806, but the die pad 804 does not extend outward past an outer perimeter 810 of a mold compound 812 that covers the semiconductor die 802 and die pad 804.

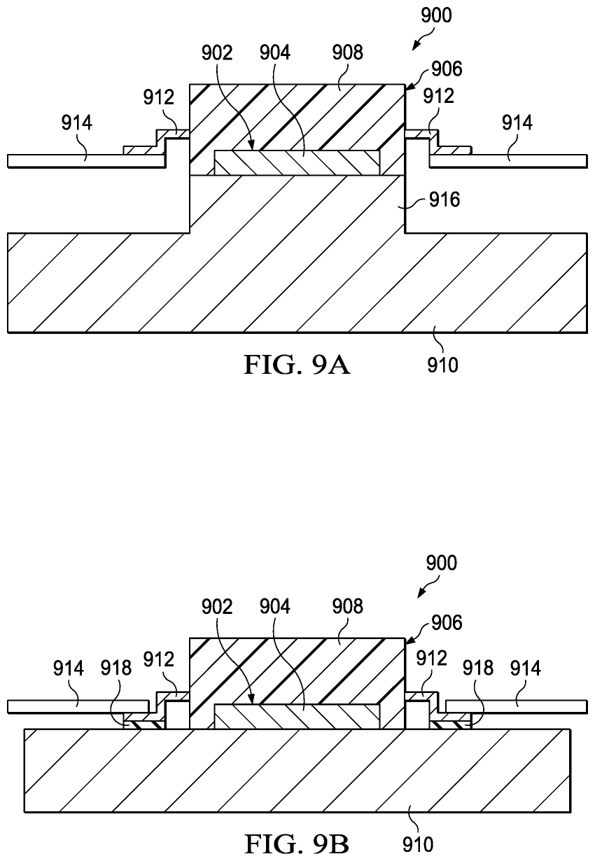

Referring now to FIGS. 9A and 9B, force sensors 900 that may be the force sensor 100 in FIG. 1 are shown according to some examples. FIGS. 9A and 9B may be collectively referred to herein as “FIG. 9.” The force sensors 900 shown in FIGS. 9A and 9B may be similar to the force sensor 200 shown in FIGS. 2A-2D and may include a number of the same components described above (however, some of these shared components may not be shown in FIGS. 9A and 9B so as to simplify the drawings and the description below).

Force sensors 900 shown in FIGS. 9A and 9B may include a mounting frame 902 having mounting pads 904 extending outward from an outer perimeter 906 of a mold compound 908. As was described above for force sensor 200 in FIGS. 2A-2D, the mounting pads 904 (one of the mounting pads 904 is not visible in FIGS. 9A and 9B) are secured to a member 910 of interest which may be a part or component of a mechanical system (e.g., shaft, strut, column, beam, casing), and forces experienced by the member 910 may be transferred to the force sensor 900 via the engagement with mounting pads 904.

Also, the force sensors 900 include conductive terminals 912 that also extend outward from mold compound 908. The conductive terminals 912 may be coupled to suitable conductive pads or members (not shown) on a printed circuit board (PCB) (or multiple PCBs) 914. The PCBs 914 may be separated from the outer surface of member 910 to prevent forces experienced by the member 910 from damaging the PCBs 914 or components coupled thereto. In FIG. 9A, the mounting pads 904 may be engaged with a projection 916 defined along the surface of the member 910. Accordingly, conductive terminals 912 may be raised above the surface of member 910 to engage with PCBs 914 as shown. In FIG. 9B, an isolating material 918 is placed between the conductive terminals 912 and the outer surface of the member 910 to prevent electrical shorts between the conductive terminals 912 and the member 910 during operations.

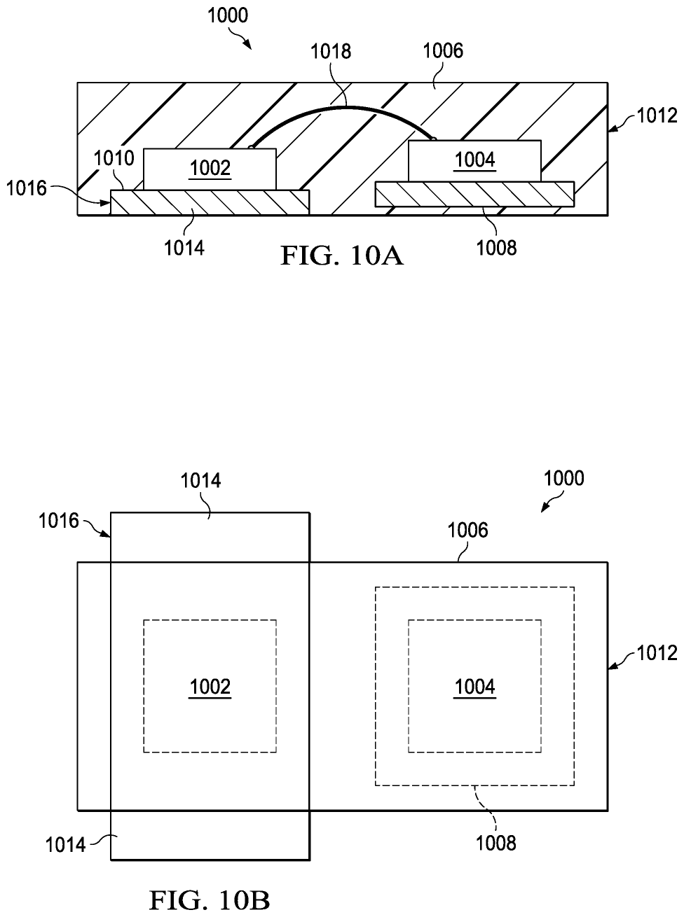

Referring now to FIGS. 10A and 10B, a force sensor 1000 that may be the force sensor 100 in FIG. 1 is shown according to some examples. FIGS. 10A and 10B may be collectively referred to herein as “FIG. 10.” The force sensor 1000 shown in FIGS. 10A and 10B may be similar to the force sensor 200 shown in FIGS. 2A-2D and may include a number of the same components described above (however, some of these shared components may not be shown in FIGS. 10A and 10B so as to simplify the drawings and the description below).

Force sensor 1000 includes a first semiconductor die 1002 and a second semiconductor die 1004 covered by a mold compound 1006. The second semiconductor die 1004 may be mounted to a die pad 1008 that may also be covered by the mold compound 1006. In some examples, the die pad 1008 may be exposed (e.g., partially, wholly) out of the mold compound 1006. The first semiconductor die 1002 is mounted to a die pad 1010 that extends beyond an outer perimeter 1012 of the mold compound 1006 to form a pair of mounting pads 1014 in the manner described above for sensor 200 (e.g., mounting pads 230). Thus, the die pad 1010 and mounting pads 1014 may together define or form a mounting frame 1016 for force sensor 1000 that is similar to mounting frame 232 of force sensor 200 (FIGS. 2A-2D).

The first semiconductor die 1002 and the second semiconductor die 1004 are electrically coupled to one another via wire bond(s) 1018 and/or any other suitable electrically coupling. During operations mounting pads 1014 of mounting frame 1016 are secured to a member of interest (e.g., shaft 102 in FIG. 1) so forces are transferred through the mounting frame 1016 to the first semiconductor die 1002 as described above. The first semiconductor die 1002 may include a circuit (e.g., circuit 208 shown in FIGS. 2C and 2D and described above) that is to detect the transferred forces from mounting frame 1016 in the manner described above (e.g., via piezoresistive changes in the circuit). The first semiconductor die 1002 may output a signal including the detected forces (or a value or values that are indicative of the detected forces) to the second semiconductor die 1004. The second semiconductor die 1004 may include a circuit that may conduct further signal processing and/or that may communicate the detected forces (or signal indicative thereof) to another device or component.

Without being limited to this or any other theory, by providing two semiconductor dies 1002, 1004 in which the second semiconductor die 1004 is not directly mounted to the member of interest, the second semiconductor die may be insulated from the forces transferred to the first semiconductor die 1002 via mounting frame 1016 such that damage to the components (e.g., circuit, silicon) of the second semiconductor die 1004 may be prevented or reduced in likelihood. In addition, providing two semiconductor dies (e.g., first semiconductor die 1002 and second semiconductor die 1004) may allow more space for circuits thereby increasing the functional capabilities of force sensor 1000.

Still other examples are contemplated that include a combination of features from other examples described above. Specifically, other force sensors contemplated herein may include any combination of the features described above for force sensors 100, 200, 300, 400, 500, 600, 700, 800, 900, 1000 etc.

The examples described above include force sensors including mounting frames for mounting the force sensors to a member of interested (e.g., a rotating shaft, a beam). In some examples, the force sensors may include a semiconductor die that is secured to the member via the mounting frame. As described above, by securing the force sensor to the member of interested via a mounting frame, the function and sensitivity of the force sensor may be enhanced.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture by an end-user and/or a third-party.

While certain components may be described herein as being of a particular process technology, these components may be exchanged for components of other process technologies.

Unless otherwise stated, “about,” “approximately,” or “substantially” preceding a value means+/−10 percent of the stated value. Modifications are possible in the described examples, and other examples are possible within the scope of the claims.

What is claimed is:

1. A force sensor, comprising:
a semiconductor die;
a die pad coupled to the semiconductor die, the semiconductor die configured to detect a force in the die pad;
a mold compound covering the semiconductor die and having an outer perimeter, a first side, and a second side opposite the first side, the outer perimeter extending between the first side and the second side, the die pad exposed out of the mold compound along the first side; and
a mounting frame engaged with the die pad along the second side of the mold compound, the mounting frame including multiple mounting pads extended outward in multiple directions from the outer perimeter.

2. The force sensor of claim 1, wherein the die pad and the mounting frame form a monolithic body.

3. The force sensor of claim 2, wherein the multiple mounting pads are in a common plane with the die pad.

4. The force sensor of claim 2, wherein the die pad is in a first plane and the mounting pads are in a second plane that is spaced from the first plane.

5. The force sensor of claim 4, wherein the mounting frame includes a portion and multiple connection portions, wherein the portion is engaged with the die pad and lies along a first plane, and wherein the connection portions extend from the portion to the mounting pads at a non-zero angle θ to the first plane.

6. The force sensor of claim 5, wherein the angle θ is greater than 90°.

7. The force sensor of claim 5, wherein the portion is positioned between the mounting pads and the first side along an axis extending through the first side and the second side.

8. The force sensor of claim 5, wherein the first side and the second side are positioned between the mounting pads and the portion along an axis extending through the first side and the second side.

9. The force sensor of claim 1, including multiple conductive terminals extending outward from the outer perimeter that are coupled to the semiconductor die.

10. A force sensor, comprising:
a semiconductor die configured to detect a force;
a mold compound covering the semiconductor die, the mold compound including an outer perimeter; and
a die pad including:
a portion engaged with the semiconductor die; and
multiple mounting pads extended beyond the outer perimeter of the mold compound on opposite sides of the mold compound.

11. The force sensor of claim 10, wherein multiple mounting pads are in a common plane with the portion.

12. The force sensor of claim 10, wherein the portion is in a first plane and the mounting pads are in a second plane that is spaced from the first plane.

13. The force sensor of claim 12, wherein the die pad includes multiple connection portions extending from the portion to the mounting pads at a non-zero angle θ relative to the first plane.

14. The force sensor of claim 13, wherein the angle θ is equal to 90°.

15. The force sensor of claim 13, wherein the angle θ is an obtuse angle.

16. The force sensor of claim 13, wherein the connection portions extend through the mold compound.

17. A force sensor, comprising:
a semiconductor die configured to detect a force;
a die pad coupled to the semiconductor die;
a mold compound covering the semiconductor die and having an outer perimeter, a first side, and a second side opposite the first side, the outer perimeter extending between the first side and the second side, the die pad exposed out of the mold compound along the first side; and
a mounting frame engaged with the die pad along the first side of the mold compound, the mounting frame having multiple mounting pads positioned outside of the outer perimeter on opposing sides of the mold compound.

18. The force sensor of claim 17, wherein the mounting pads are in a different plane than the die pad.

19. The force sensor of claim 18, wherein the mounting frame includes:
a portion that lies along a plane; and
multiple connection portions extending from the portion to the mounting pads, at a non-zero angle to the plane.

20. The force sensor of claim 19, wherein the die pad and the mounting frame are formed as a monolithic body.
